(19) United States
(12) Patent Application Publication
(10) Pub. No.: US 2015/0024215 A1
(43) Pub. Date: Jan. 22, 2015

(54) SILVER-PLATED COATED BODY

(71) Applicant: Mitsubishi Paper Mills Limited, Sumida-ku, Tokyo (JP)

(72) Inventors: Masao Utsumi, Sumida-ku (JP); Motozo Yamano, Sumida-ku (JP); Kazuhiko Ibaraki, Sumida-ku (JP)

(21) Appl. No.: 14/383,139

(22) PCT Filed: Mar. 14, 2013
(86) PCT No.: PCT/JP2013/057175

§ 371 Date: Sep. 5, 2014

(30) Foreign Application Priority Data
Mar. 27, 2012 (JP) 2012-071654
Sep. 27, 2012 (JP) 2012-213780
Nov. 30, 2012 (JP) 2012-262594

(51) Int. Cl. C23C 18/42; H05K 9/00

(52) U.S. Cl. CPC C23C 18/42; H05K 9/0084
USPC 428/418; 428/457; 428/447; 428/425.8

(57) ABSTRACT

Provided is a silver-plated coated body that is excellent in interlayer adhesion and tarnish resistance. The silver-plated coated body has a silver film layer and a topcoat layer as essential layers on a substrate, the topcoat layer containing at least one kind selected from thiourea and thiourea derivatives, and at least one kind selected from thiol organic acids and thiol organic acid derivatives.

### TECHNICAL FIELD

The present invention relates to a silver-plated coated body having a silver film layer on a substrate.

### BACKGROUND ART

Silver has the most highly reflective luster among metals and thus silver-plated coated bodies having a silver film layer on a substrate such as metals and plastics are used as decorative materials, reflective materials or the like. In addition, silver-plated coated bodies are effectively used as, for example, electromagnetic shielding materials because of the high electrical conductivity of the silver film layer. However, silver-plated coated bodies are unsatisfactory in durability because silver tends to tarnish, e.g. turn black or white, due to its high reactivity with sulfides, and is easily damaged on the surface due to its softness. For these reasons, silver-plated coated bodies are not yet widely applicable to practical industrial products.

In order to deal with these problems unique to silver, topcoat layer formation from various hard-coat materials on the surface of the silver film layer has been suggested. For example, Patent Literature 1 describes that liquid epoxy resins, unsaturated polyester resins, fluororesins, acrylic resins, melamine resins, silicone resins or the like can be used in a topcoat layer. Patent Literature 2, Patent Literature 3, etc. describe the use of a silicone-acrylic paint having a specific glass transition temperature in a topcoat layer. Patent Literature 4, Patent Literature 5, etc. describe that ultraviolet-curable resins or electron beam-curable resins may be used in a topcoat layer.

However, when a silver film layer covered by such a topcoat layer is exposed to a high-humidity and high-temperature environment, or particularly an atmosphere rich in salt water, the adhesive strength between the silver film layer and the topcoat layer will be considerably reduced because the silver film layer is highly hydrophilic.

The use of various kinds of silane coupling agents for improving the adhesion between a silver film layer and a topcoat layer is known and disclosed in Patent Literature 3 mentioned above, Patent Literature 6, etc.

Meanwhile, Patent Literature 7 describes that the surface of a copper substrate pretreated with an acidic liquid containing thiourea or its derivative is plated with electroless tin or solder to improve the adhesion between the copper substrate and the plating layer. Patent Literature 8 describes a metal surface-coating composition containing a cationic resin and/or an amphoteric resin, and an organic sulfur compound such as thiourea analogs.

### CITATION LIST

### Patent Literature

Patent Literature 1: JP-A 2000-129448
Patent Literature 2: JP-A 2003-155580
Patent Literature 3: JP-A 2004-203014
Patent Literature 4: JP-A 2008-110101
Patent Literature 5: JP-A 2008-176050
Patent Literature 6: JP-A 2005-307179
Patent Literature 7: JP-A 06-41762
Patent Literature 8: JP-A 2001-247826

### SUMMARY OF INVENTION

### Technical Problem

The techniques disclosed in Patent Literature 6 etc. fail to provide sufficient adhesion between the silver film layer and the topcoat layer under an environment rich in salt water, and thus further improvement of interlayer adhesion is required. Further, when thiourea compounds as described in Patent Literature 7 and 8 are used in contact with a silver film layer, silver may tarnish, e.g. turn white or black, and thus tarnish resistance also needs to be improved. Therefore, an object of the present invention is to provide a silver-plated coated body that is excellent in interlayer adhesion and tarnish resistance.

### Solution to Problem

The object of the present invention can be achieved by a silver-plated coated body having a silver film layer and a topcoat layer as essential layers on a substrate, the topcoat layer containing at least one kind selected from thiourea and thiourea derivatives, and at least one kind selected from thiol organic acids and thiol organic acid derivatives. It is preferred that the at least one kind selected from thiol organic acids and thiol organic acid derivatives is at least one kind selected from mercaptopropionic acid derivatives and thioglycolic acid derivatives, and it is also preferred that the topcoat layer further contains a silane coupling agent. Preferably, an undercoat layer containing a urethane resin and an epoxy resin is present between the substrate and the silver film layer. In this case, the content ratio of the urethane resin to the epoxy resin (the ratio of the urethane resin content to the epoxy resin content) in the undercoat layer is preferably 45:55 to 75:25 (mass ratio). More preferably, an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

### Advantageous Effects of Invention

According to the present invention, a silver-plated coated body that is excellent in interlayer adhesion and tarnish resistance can be provided.

### DESCRIPTION OF EMBODIMENTS

The silver-plated coated body of the present invention has a silver film layer and a topcoat layer as essential layers on a substrate. The topcoat layer according to the present invention preferably contains a resin such as a heat-curable resin and an ultraviolet-curable resin.

In the silver-plated coated body of the present invention, the topcoat layer contains at least one kind selected from thiourea and thiourea derivatives (hereinafter referred to as thiourea compounds), and at least one kind selected from thiol organic acids and thiol organic acid derivatives (hereinafter referred to as thiol organic acid compounds). As shown in Examples described later, thiourea compounds cause silver to tarnish, e.g. turn black. The present inventors found that a combined use of a thiourea compound, which causes silver tarnishing when used alone, and a thiol organic acid compound in a topcoat layer can significantly improve the adhesion of the silver film layer and the topcoat layer without silver tarnishing.

Among the thiourea compounds used in the present invention, thiourea is a compound represented by H₂N—C(═S)—NH₂ and also called thiocarbamide. Among the thiourea compounds used in the present invention, examples of the thiourea derivative include 1-methylthiourea, 1,3-dimethylthiourea, diethylthiourea (for example, 1,3-diethylthiourea), trimethylthiourea, 1,3-diisopropylthiourea, allylthiourea, acetylthiourea, ethylenethiourea, 1,3-diphenylthiourea, thiourea dioxide, thiosemicarbazide, S-methylisothiourea sulfate, tributylthiourea, benzylisothiourea hydrochloride, 1,3-dibutylthiourea, 1-naphthylthiourea, tetramethylthiourea and 1-phenylthiourea.

Among the thiol organic acid compounds used in the present invention, the thiol organic acid is an organic acid having one or more thiol groups. Among the thiol organic acid compounds used in the present invention, the thiol organic acid derivative is a derivative of an organic acid having one or more thiol groups, and is preferably a derivative of a carboxylic acid having one or more thiol groups. Examples of the thiol organic acid compounds used in the present invention include thiol compounds such as thiomalic acid, 2-mercaptoethyl octanoate and 2-mercaptopropionic acid; mercaptopropionic acid derivatives such as 3-mercaptopropionic acid, methoxybutyl mercaptopropionate, octyl mercaptopropionate, tridecyl mercaptopropionate, trimethylolpropane tris(thiopropionate) and pentaerythritol tetrakis thiopropionate; and thioglycolic acid derivatives such as thioglycolic acid, ammonium thioglycolate, monoethanolamine thioglycolate, methyl thioglycolate, octyl thioglycolate, methoxybutyl thioglycolate, ethylene glycol bis(thioglycolate), butanediol bis(thioglycolate), trimethylolpropane tris(thioglycolate) and pentaerythritol tetrakis thioglycolate. These are available as commercial products. In particular, preferred is at least one kind selected from the mercaptopropionic acid derivatives and the thioglycolic acid derivatives.

One kind or a combination of two or more kinds of the thiourea compounds are contained in the topcoat layer, and the content, i.e. the total amount of the thiourea compound(s), is preferably 0.1 to 5% by mass, and more preferably 0.5 to 3% by mass relative to the resin solid content of the topcoat layer. One kind or a combination of two or more kinds of the thiol organic acid compounds are contained in the topcoat layer, and the content, i.e. the total amount of the thiol organic acid compound(s), is preferably 1 to 20% by mass, and more preferably 5 to 10% by mass relative to the resin solid content of the topcoat layer.

According to the present invention, the topcoat layer preferably contains a silane coupling agent in addition to the thiourea compound and the thiol organic acid compound. The addition of a silane coupling agent provides further improvement in the interlayer adhesion after a salt spray test and in the tarnish resistance after a heat test.

As the silane coupling agent used in the present invention, conventionally known silane coupling agents are usable and the examples include vinyltriethoxysilane, vinyltrimetoxysilane, vinyltris(2-methoxyethoxy)silane, vinylmethyldimethoxysilane, 3-methacryloxypropyltriethoxysilane, 3-methacryloxypropyltrimethoxysilane, 2-(3,4-epoxycyclohexyl)ethyltrimethoxysilane, 3-glycidoxypropyltrimetoxysilane, 3-mercaptopropyltrimethoxysilane, 3-mercaptopropyltriethoxysilane, 3-octanoylthio-1-propyltriethoxysilane, 3-aminopropyltrimethoxysilane, 3-aminopropyltriethoxysilane, N-(2-aminoethyl)-3-aminopropyltrimethoxysilane, 3-(N-phenyl)aminopropyltrimethoxysilane, 3-glycidoxypropyltriethoxysilane, 3-ureidopropyltriethoxysilane, 3-isocyanatepropyltriethoxysilane and 3-isocyanatepropyltrimethoxysilane.

Regarding the amount of the silane coupling agent in the topcoat layer, the total amount of the silane coupling agent, the thiourea compound (s) and the thiol organic acid compound (s) as solids is preferably 1 to 30% by mass, and more preferably 5 to 20% by mass relative to the resin solid content of the topcoat layer.

The topcoat layer is preferably provided directly on the silver film layer in the silver-plated coated body of the present invention.

Examples of the heat-curable resin contained in the topcoat layer include liquid epoxy resins, unsaturated polyester resins, fluororesins, acrylic resins, melamine resins and silicone resins, as described in JP-A 2000-129448; an acrylic silicone resin as described in JP-A 2003-155580; and a two-pack type polyurethane-based curable resin and a two-pack type acrylic modified silicone-based curable resin as described in JP-A 2002-256445. Further, the following commercially available heat-curable resins are preferably used: “PTC-02UH (10B)” (acrylic silicone resin) manufactured by Fujikura Kasei Co., Ltd.; “Origi-Zug #100” (acrylic silicone resin) manufactured by Origin Electric Co., Ltd.; “HIGH POLYNAL No. 800S” (acrylic silicone resin), “O-MACK No. 100(E) Clear FV” (acrylic silicone resin) and “Neo Hard Clear H” (high-hardness acrylic resin) manufactured by Ohashi Chemical Industries Ltd.; etc.

Meanwhile, in the case where an ultraviolet-curable resin is used in the topcoat layer, the production time can be reduced. The ultraviolet-curable resin is a resin curable by ultraviolet radiation. Preferably used is mainly a monomeric or oligomeric compound having an ethylenically unsaturated group. Electron beam-curable resins are also included in the ultraviolet-curable resin. Specific examples of the ultraviolet-curable resin include amide monomers, (meth)acrylate monomers, urethane acrylates, polyester (meth)acrylates and epoxy(meth)acrylates. The amide monomers include amide compounds such as N-vinyl pyrrolidone, N-vinylcaprolactam and acryloylmorpholine. The (meth)acrylate monomers include hydroxyalkyl(meth)acrylates such as 2-hydroxyethyl(meth)acrylate, 2-hydroxypropyl(meth)acrylate and 2-hydroxy-3-phenylpropyl acrylate; acrylates of alkylene oxide adducts of phenol, such as phenoxyethyl(meth)acrylate, and their halogen-nucleus substituted derivatives; glycol mono- or di-(meth)acrylates such as ethylene glycol mono- or di-(meth)acrylates, methoxy ethylene glycol mono(meth)acrylates, tetraethylene glycol mono- or di-(meth)acrylates and tripropylene glycol mono- or di-(meth)acrylates; (meth)acrylic acid esters of polyols or alkylene oxide polyols such as trimethylolpropane tri(meth)acrylate, pentaerythritol tri(meth)acrylate, pentaerythritol tetra(meth)acrylate and dipentaerythritol hexaacrylate; and isocyanuric acid EO-modified di- or tri-(meth)acrylates.

Urethane (meth)acrylate oligomers include products resulting from a reaction of a hydroxyl group-containing (meth)acrylate with a product resulting from a reaction of a polyol with an organic polyisocyanate. Here, examples of the polyol include low molecular weight polyols, polyether polyols and polyester polyols. The low molecular weight polyols include ethylene glycol, propylene glycol, cyclohexane dimethanol and 3-methyl-1,5-pentanediol. The polyether polyols include polyethylene glycol and polypropylene glycol. The polyester polyols include products resulting from a reaction of any of the low molecular weight polyols and/or any of the polyether polyols, with an acid component including dibasic acids or anhydrides thereof, such as adipic acid, succinic acid, phthalic acid, hexahydrophthalic acid and terephthalic acid. Examples of the organic polyisocyanate include tolylene diisocyanate, 4,4′-diphenylmethane diisocyanate, 4,4′-dicyclohexylmethane diisocyanate, hexamethylene diisocyanate and isophorone diisocyanate. Examples of the hydroxyl group-containing (meth)acrylate include hydroxyalkyl(meth)acrylates such as 2-hydroxyethyl(meth)acrylate and 2-hydroxypropyl(meth)acrylate.

Polyester (meth)acrylate oligomers include dehydration-condensation products of a polyester polyol and (meth)acrylic acid. Examples of the polyester polyol include products resulting from a reaction of a polyol including low molecular weight polyols, such as ethylene glycol, polyethylene glycol, cyclohexane dimethanol, 3-methyl-1,5-pentanediol, propylene glycol, polypropylene glycol, 1,6-hexanediol and trimethylolpropane, and alkylene oxide adducts thereof, with an acid component including dibasic acids or anhydrides thereof, such as adipic acid, succinic acid, phthalic acid, hexahydrophthalic acid and terephthalic acid. Epoxy acrylates are compounds resulting from an addition reaction of epoxy resins with an unsaturated carboxylic acid such as (meth)acrylic acid, and include epoxy(meth)acrylates derived from bisphenol A epoxy resins; epoxy(meth)acrylates derived from phenol or cresol novolac epoxy resins; and products resulting from an addition reaction of diglycidyl polyethers with (meth)acrylic acid.

With the ultraviolet-curable resin, a photopolymerization initiator is used as needed. Examples of the photopolymerization initiator include benzoin and its alkyl ethers, such as benzoin, benzoin methyl ether, benzoin ethyl ether and benzoin isopropyl ether; acetophenones such as acetophenone, 2,2-dimethoxy-2-phenylacetophenone, 2,2-diethoxy-2-phenylacetophenone, 1,1-dichloroacetophenone, 1-hydroxyacetophenone, 1-hydroxycyclohexylphenylketone and 2-methyl-1-[4-(methylthio)phenyl]-2-morpholino-propan-1-one; anthraquinones such as 2-methylanthraquinone, 2-ethylanthraquinone, 2-tert-butylanthraquinone, 1-chloroanthraquinone and 2-amylanthraquinone; thioxanthones such as 2,4-dimethylthioxanthone, 2,4-diethylthioxanthone, 2-chlorothioxanthone and 2,4-diisopylthioxanthone; ketals such as acetophenone dimethyl ketal and benzyl dimethyl ketal; monoacylphosphine oxides or bisacylphosphine oxides, such as 2,4,6-trimethylbenzoyl diphenylphosphine oxide; benzophenones such as benzophenone; and xanthones. These photopolymerization initiators may be used alone or in combination with a photopolymerization initiation accelerator based on benzoic acids, amines or the like.

The amount of the photopolymerization initiator used is preferably 0.01 to 20% by mass, and more preferably 0.5 to 7% by mass relative to the ultraviolet-curable resin content.

The curing of the topcoat layer composition containing an ultraviolet-curable resin can be achieved by heating, electron beam irradiation, ultraviolet irradiation, etc. Examples of the means for electron beam irradiation or ultraviolet irradiation include lamp light sources such as a xenon lamp, a halogen lamp, a tungsten lamp, a high pressure mercury lamp, an ultrahigh pressure mercury lamp, a metal halide lamp, a moderate pressure mercury lamp and a low pressure mercury lamp; and laser light sources such as an argon ion laser, a YAG laser, an excimer laser and a nitrogen laser.

The thickness of the topcoat layer containing a heat-curable resin is preferably in the range of 10 to 25 μm, and the thickness of the topcoat layer containing an ultraviolet-curable resin is preferably in the range of 3 to 10 μm.

In the topcoat layer, a coloring material and/or an additive may be further contained as needed. Examples of the coloring material that may be further contained in the topcoat layer include colorants such as pigments and dyes, and the addition of such a coloring material can adjust the color tone of the layer. The coloring material is more preferably the one whose absorption wavelength does not overlap with that of the photopolymerization initiator because such a coloring material does not hinder the activity of the photopolymerization initiator. Examples of the pigment include, but are not limited to, organic pigments such as carbon black, quinacridone, naphthol red, cyanine blue, cyanine green and hansa yellow; and inorganic pigments such as titanium oxide, aluminum oxide, calcium carbonate, barium sulfate, mica, red iron oxide and metal oxide composites. These pigments can be used alone or in a combination of two or more kinds thereof. The method for dispersing the pigment is not particularly limited, and conventional methods may be employed. For example, a pigment powder is directly dispersed by use of a dynomill, a paint shaker, a sand mill, a ball mill, a kneader, a roll, a dissolver, a homogenizer, an ultrasonic vibrator, a stirrer or the like. At this dispersing step, a dispersant, a dispersing aid, a thickener, a coupling agent, etc. can be used. The amount of the pigment used is not particularly limited because the masking property varies with the kind of pigment, but for example, the amount of the pigment used is preferably 0.01 to 10% by mass, and more preferably 0.1 to 5% by mass relative to the resin solid content in the total amount of the topcoat layer components.

Examples of the dye include, but are not limited to, azo dyes, anthraquinone dyes, indigoid dyes, sulfide dyes, triphenylmethane dyes, xanthene dyes, alizarin dyes, acridine dyes, quinonimine dyes, thiazole dyes, methine dyes, nitro dyes and nitroso dyes. These dyes can be used alone or in a combination of two or more kinds thereof. The amount of the dye used is not particularly limited because the masking property varies with the kind of dye, but for example, the amount of the dye used is preferably 0.01 to 10% by mass, and more preferably 0.1 to 5% by mass relative to the resin solid content in the total amount of the topcoat layer components.

Examples of the additive that may be further contained in the topcoat layer include leveling agents, metal powder, glass powder, antimicrobial agents, antioxidants and ultraviolet absorbers.

The method for the formation of the topcoat layer generally comprises dissolving the topcoat layer components in an organic solvent and applying the resulting paint. The method for applying the paint may be any conventionally known coating method, and for example, a photogravure roll method, a reverse roll method, a dip-and-roll method, a bar coater method, a die coater method, a curtain coater method, a knife coater method, an air spray method, an airless spray method, a dipping method or the like can be employed.

Examples of the organic solvent include, but are not limited to, hydrocarbons such as cyclohexane and “Solvesso 100” manufactured by ExxonMobil Chemical; alcohols such as methanol, ethanol, isopropyl alcohol, butyl alcohol and cyclohexanol; esters such as ethyl acetate, n-butyl acetate, isobutyl acetate, amyl formate, isoamyl acetate, isobutyl acetate, butyl propionate, isopropyl butyrate, ethyl butyrate, butyl butyrate, alkyl esters, methyl lactate, ethyl lactate, methyl oxyacetate, ethyl oxyacetate, butyl oxyacetate, methyl methoxyacetate, ethyl methoxyacetate, butyl methoxyacetate, methyl ethoxyacetate and ethyl ethoxyacetate; ethers such as tetrahydrofuran, ethylene glycol monomethyl ether, ethylene glycol monoethyl ether, ethylene glycol monobutyl ether, methyl cellosolve acetate, ethyl cellosolve acetate, diethylene glycol monomethyl ether, diethylene glycol monoethyl ether, diethylene glycol monobutyl ether, propylene glycol monomethyl ether, propylene glycol monomethyl ether acetate, propylene glycol monoethyl ether acetate, propylene glycol monopropyl ether acetate, diethylene glycol dimethyl ether and diethylene glycol diethyl ether; and ketones such as methyl ethyl ketone, methyl isobutyl ketone, cyclohexanone, 2-heptanone and 3-heptanone. From these organic solvents, appropriate one(s) are selected in consideration of the solubility of the components of the undercoat layer and of the topcoat layer, as well as the improvement of the coating surface and other purposes. These organic solvents may be used alone, but are often used as a mixture of two or more kinds thereof.

Examples of the substrate used in the silver-plated coated body of the present invention include various kinds of plastic, metal, glass, ceramic or rubber materials. The plastic materials include, but are not particularly limited to, polycarbonate resins, acrylic resins, acrylonitrile butadiene-styrene (ABS) resins, vinyl chloride resins, epoxy resins, phenol resins, polyester resins including polyethylene terephthalate (PET) resins and polybutylene terephthalate (PBT) resins, fluororesins, polyethylene (PE) resins, polypropylene (PP) resins, and composite resins of any two or more of the foregoing, and further include fiber reinforced plastics (FRP), in which plastics are reinforced with organic fibers such as nylon fibers and pulp fibers. The metal materials include, but are not particularly limited to, iron, aluminum, stainless steel, copper, brass and other metals, and surface treated metals resulting from antirust or other treatments of the foregoing metals. The glass materials include, but are not particularly limited to, inorganic glass and plastic glass. On such a substrate, an undercoat layer, an adhesion promoting layer, an antirust layer, a colored layer, etc. may be formed by organic solvent coating, primer coating, powder coating, electrodeposition coating, etc.

As pretreatment of the substrate before coating, wet treatment such as detergent washing, solvent cleaning and ultrasonic cleaning is preferably carried out for removal of substances usually inhibiting coating layer adhesion to the substrate. In addition to primer coating as mentioned above as adhesion promoting treatment, dry treatment such as corona treatment, ultraviolet irradiation treatment and electron beam irradiation treatment may be carried out.

The undercoat layer is not necessarily essential for the present invention, but improving the roughness of the substrate surface is an effective means in order to utilize the good reflectivity of the silver film layer. For this reason, it is desirable to provide an undercoat layer on the substrate. In this case, the undercoat layer is required to have good adhesion to the substrate and to have excellent adhesion to the silver film layer to be formed on the undercoat layer. The undercoat layer is also required to have a smooth surface. As a paint for the undercoat layer, for example, polyol-based paints containing a mixture of a polymer or an oligomer having terminal hydroxyl groups, such as alkyd polyols, polyester polyols and acrylic polyols, and an isocyanate compound as a curing agent; epoxy-based paints containing a mixture of an epoxy resin and an amine compound as a curing agent; or the like can be selected depending on the substrate and the characteristics required of a coated body. The thickness of the undercoat layer is preferably 5 to 30 μm, but is not particularly limited.

The undercoat layer of the present invention preferably contains a urethane resin and an epoxy resin. Examples of the urethane resin contained in the undercoat layer of the present invention include urethane resins obtainable by mixing a polymer or an oligomer having terminal hydroxyl groups, such as alkyd polyols, polyester polyols, acrylic polyols, polyether polyols, polycarbonate polyols and polycaprolactone polyols, with an isocyanate compound as a curing agent. Particularly preferred are urethane resins obtainable by mixing an acrylic polyol with an isocyanate compound.

Examples of the isocyanate compound used as a curing agent include a biuret form, an isocyanurate form, an adduct form and a bifunctional form of isocyanates. Particularly preferred is a biuret form of isocyanate compounds, and for example, “DURANATE 24A-100 (trade name),” “DURANATE 22A-75P (trade name)” and “DURANATE 21S-75E (trade name),” all of which are manufactured by Asahi Kasei Corporation, can be used.

As the above-mentioned urethane resin, commercial products can be purchased and used. For example, as the urethane resin obtainable by mixing an acrylic polyol with an isocyanate compound, which is preferably used in the present invention, for example, “Mirror Shine Undercoat Clear D-1 (trade name)” and “Under Black No. 128 (trade name),” both of which are manufactured by Ohashi Chemical Industries Ltd., can be used.

Examples of the epoxy resin contained in the undercoat layer of the present invention include glycidyl ether epoxy resins, glycidyl ester epoxy resins and glycidyl amine epoxy resins, and preferred are glycidyl ether epoxy resins. The glycidyl ether epoxy resins include bisphenol A epoxy resins, bisphenol F epoxy resins, bisphenol S epoxy resins and novolac epoxy resins, and particularly preferred are bisphenol A epoxy resins. The epoxy equivalent of the epoxy resin is preferably 100 to 800, and more preferably 200 to 600. When the epoxy equivalent of the epoxy resin is less than 100 or more than 800, the adhesion between the undercoat layer and the silver film layer may be insufficient. As the above-mentioned epoxy resin, for example, “GLYCI-ALE BPP-350 (trade name)” (manufactured by Sanyo Chemical Industries, Ltd.; epoxy equivalent: 340), “850-5 (trade name)” (manufactured by DIC Corporation; epoxy equivalent: 183 to 193), “ADEKA RESIN EP-4000 (trade name)” (manufactured by ADEKA CORPORATION; epoxy equivalent: 320), “ADEKA RESIN EP-4005 (trade name)” (manufactured by ADEKA CORPORATION; epoxy equivalent: 510), etc. can be used.

The content ratio of the urethane resin to the epoxy resin (the ratio of the urethane resin content to the epoxy resin content) in the undercoat layer of the present invention is preferably in a specific range, which is preferably from 40:60 to 80:20 (mass ratio), and more preferably from 45:55 to 75:25 (mass ratio).

In addition to the above-described urethane resin and epoxy resin, another resin can be contained in the undercoat layer of the present invention. Examples of such a resin include polyvinyl chloride, polycarbonate, polystyrene, polymethylmethacrylate, polyester, polysulfone, polyphenylene oxide, polybutadiene, poly(N-vinylcarbazole), hydrocarbon resins, ketone resins, phenoxy resins, polyamide, ethyl cellulose, vinyl acetate, ABS resins, melamine resins, urea resins, benzoguanamine resins, unsaturated polyester resins, alkyd resins and silicone resin alkoxy titanium esters. In this case, the amount of the additional resin is preferably 30% by mass or less, and more preferably 25% by mass or less relative to the total amount of the urethane resin and the epoxy resin.

The undercoat layer preferably contains a curing agent in addition to the above-described urethane resin and epoxy resin. Examples of the curing agent include epoxy compounds, oxazoline compounds, aziridine compounds, isocyanate compounds, amine compounds, mercaptan compounds, imidazole compounds and acid anhydrides, and particularly preferred are isocyanate compounds. The isocyanate compounds include the commercial products listed above as examples of the isocyanate compound used to produce urethane resins as well as a commercial curing agent available as “Under Clear Curing Agent-N” from Ohashi Chemical Industries Ltd. The amount of the curing agent in the undercoat layer is preferably 5 to 30% by mass relative to the total amount of the urethane resin and the epoxy resin.

In the case of the use of a substrate that should not be dried at a high temperature of 100° C. or higher at which heat deformation and/or heat contraction may occur, a curing accelerator can be additionally used in the undercoat layer. For improvement of the surface condition of the undercoat layer, a leveling agent can be additionally used in the undercoat layer.

Examples of the curing accelerator for the urethane resin include “Curing Accelerator for Urethane” manufactured by Nagashima Co., Ltd.; “Drying Accelerator A” manufactured by SANSEI PAINT Co., Ltd.; and phenol salts, oleic acid salts and octylic acid salts of 1,8-diazabicyclo[5.4.0]undecene-7 or 1,5-diazabicyclo[4.3.0]nonene-5, which are commercially available as curing accelerators for urethane from NittoBussan Co., LTD., San-Apro Ltd., NIHON KAGAKU SANGYO CO., LTD., Mitsubishi Chemical Corporation, etc. Examples of the curing accelerator for the epoxy resin include various kinds of amines commercially available from San-Apro Ltd. Examples of the leveling agent include silicone-based leveling agents, fluorine-based leveling agents, etc. commercially available from TOSHIN KAGAKU CO., LTD., DIC Corporation, BYK, etc. The amount of the curing accelerator used is preferably 0.1 to 2% by mass, and more preferably 0.3 to 1% by mass relative to the amount of the resin components in the undercoat layer. The amount of the leveling agent used is preferably 0.001 to 1% by mass, and more preferably 0.005 to 0.05% by mass relative to the amount of the resin components in the undercoat layer.

The method for the formation of the undercoat layer generally comprises dissolving the above-described components in an organic solvent and applying the resulting paint. Examples of the organic solvent may be the same as those described above for the topcoat layer. The method for applying the paint may be any conventionally known coating method as with the case of the topcoat layer coating.

In the silver-plated coated body of the present invention, at least one selected from the undercoat layer and the topcoat layer preferably contains a heterocyclic compound having a thiol group and a hydrophobic group, and an octanol/water partition coefficient (Log P) of 3.5 or more. The octanol/water partition coefficient can be readily calculated by Crippen's method.

In the present invention, examples of the hydrophobic group include an alkyl group, an alkylene group and an aryl group. These may have a substituent, and the alkyl group and the alkylene group may be branched. Specific examples of the alkyl group include a methyl group, an ethyl group, a butyl group, an isopropyl group, a n-hexyl group, a n-heptyl group, a n-octyl group, a n-decyl group, a n-tetradecyl group and a n-hexadecyl group. Specific examples of the alkylene group include divalent groups derived from these alkyl groups. The alkyl or alkylene group preferably has four or more carbon atoms. Specific examples of the aryl group include a phenyl group and a naphthyl group. Such a hydrophobic group is preferably bound to the heterocyclic ring, and is preferably bound to the heterocyclic ring via a sulfur atom, a nitrogen atom, an oxygen atom or the like. The aryl group may be condensed with the heterocyclic ring as a mother nucleus. The alkyl group, the alkylene group and the aryl group may also have a substituent such as the above-listed alkyl groups and aryl groups via a sulfur atom, a nitrogen atom, an oxygen atom or the like.

In the heterocyclic compound having a thiol group and a hydrophobic group, and a Log P of 3.5 or more, the Log P of 3.5 or more is attributable to the presence of such an hydrophobic group, and the Log P is more preferably 4.0 or more.

Specific examples of the heterocyclic ring include imidazole, imidazolidine, imidazoline, oxadiazole, oxazine, thiadiazole, triazole, thiazolidine, tetrazole, triazine, triazole, piperazine, piperidine, pyrazine, pyrazole, pyrazolidine, pyridine, pyridazine, pyrimidine, pyrrole and pyrrolidine. Particularly preferred heterocyclic rings are oxadiazole, thiadiazole and triazole. The heterocyclic compound having a thiol group and a hydrophobic group, and a Log P of 3.5 or more may have a plurality of such heterocyclic rings in a molecule. In this case, a plurality of heterocyclic rings may be linked by an alkylene group, and a plurality of heterocyclic rings may be linked by an alkylene group via a sulfur atom, a nitrogen atom, an oxygen atom or the like.

Specific examples of the heterocyclic compound having a thiol group and a hydrophobic group, and a Log P of 3.5 or more are shown below, but the present invention is not limited to these. The Log P values shown in the figures were calculated by Crippen's method.

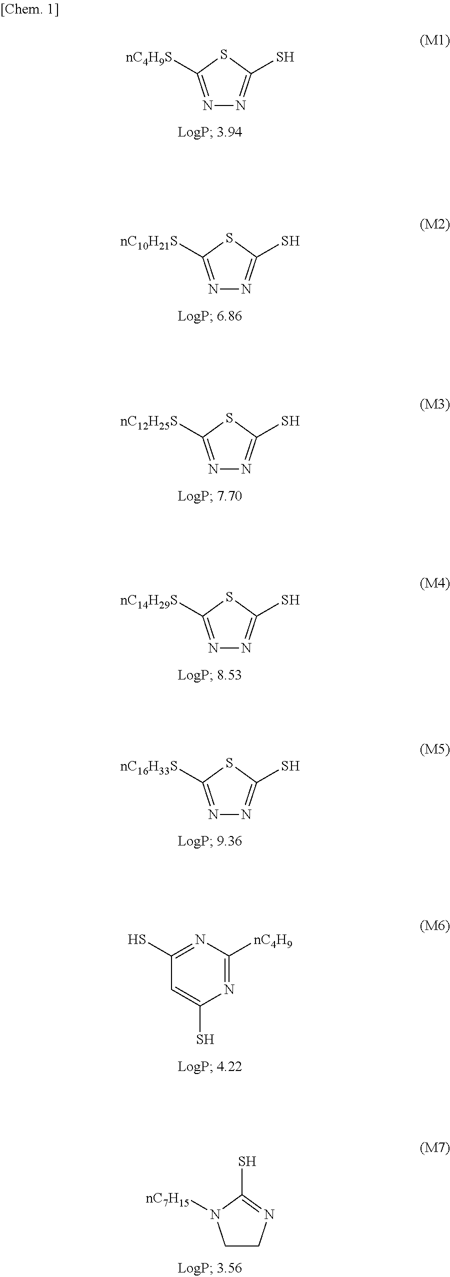

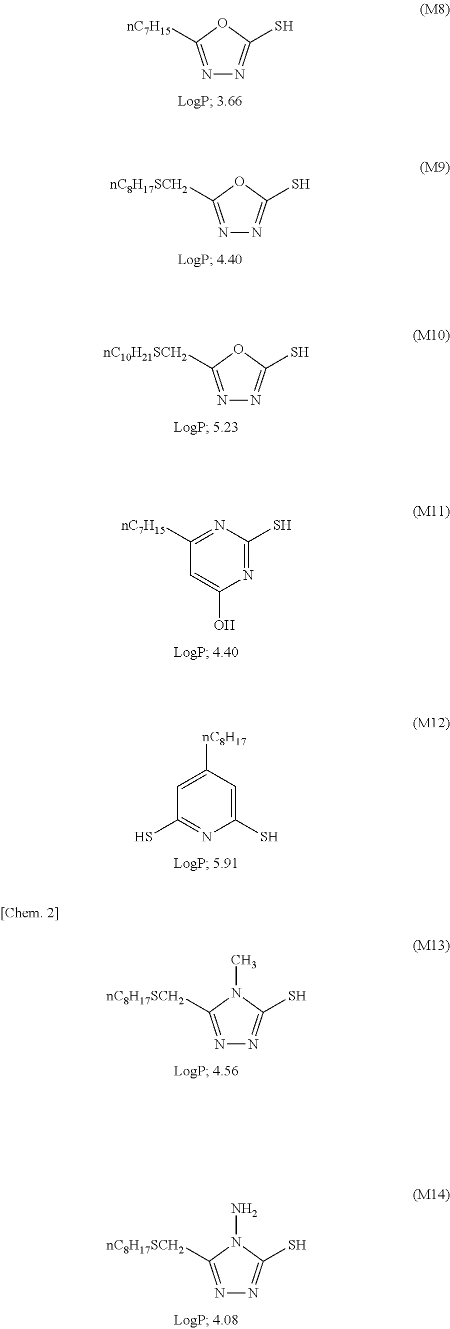

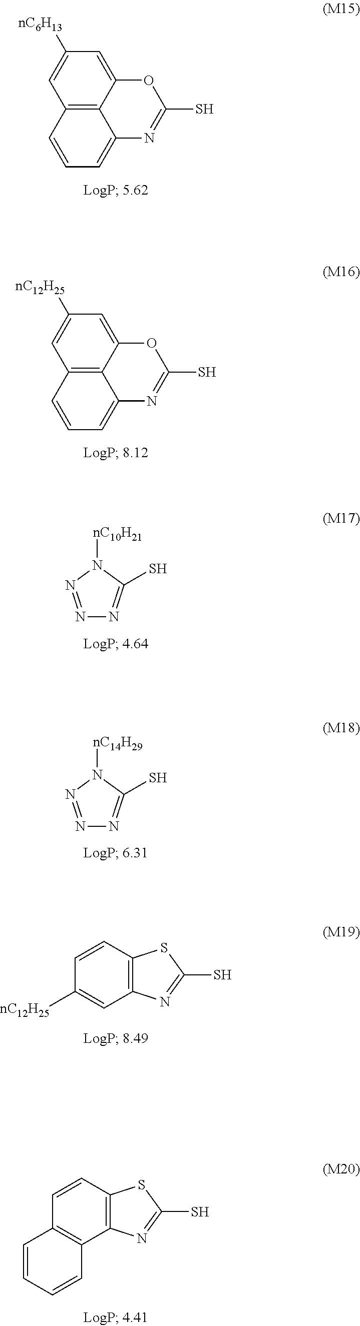

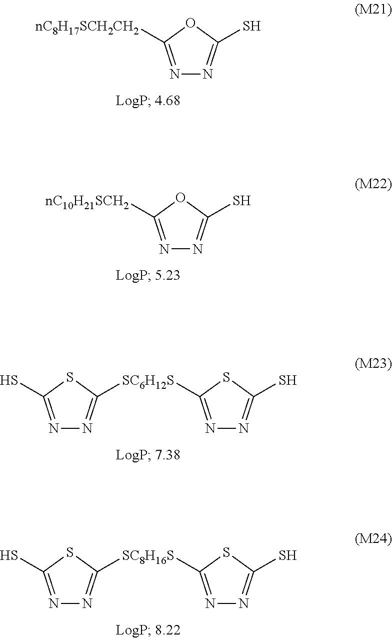

At least one selected from the undercoat layer and the topcoat layer can contain one kind or a combination of two or more kinds of the heterocyclic compounds having a thiol group and a hydrophobic group, and a Log P of 3.5 or more. The content, i.e. the total amount of the heterocyclic compound(s) having a thiol group and a hydrophobic group, and a Log P of 3.5 or more, is preferably 0.01 to 40% by mass, and more preferably 0.1 to 10% by mass relative to the resin solid content of the topcoat layer or the undercoat layer.

In the silver-plated coated body of the present invention, the silver film layer may be provided directly on any substrate described above or provided on the undercoat layer described above. The silver film layer has good reflective luster and thus is preferably formed by electroless plating using a silver mirror reaction. Here, a common method for the formation of a silver film layer is described as an example, where a silver film layer is formed on the surface of an undercoat layer by electroless plating using a silver mirror reaction.

Firstly, for activation of an undercoat layer, the surface of the undercoat layer provided on a substrate is treated with a stannous chloride-containing activation liquid for a silver mirror reaction to fix stannous ions on the surface of the undercoat layer. Then, a silver film layer is formed by a silver mirror reaction on the activated undercoat layer.

The treatment of the undercoat layer with a stannous chloride-containing activation liquid for a silver mirror reaction can be carried out by, for example, dipping a substrate having an undercoat layer thereon in the activation liquid for a silver mirror reaction; or applying the activation liquid for a silver mirror reaction containing a stannous chloride etc. on the undercoat layer surface. The method for applying the activation liquid can be selected as appropriate for the shape of the substrate etc., but particularly preferred is spray coating because it can be employed regardless of the shape of the substrate. The extra activation liquid adherent to the undercoat layer surface may be washed off with deionized water or purified distilled water.

Examples of the stannous chloride-containing activation liquid for a silver mirror reaction include activation liquids described in Kinzoku Hyoumen Gijyutsu Binran (Metal Finishing Technical Handbook) (edited by the Metal Finishing Society of Japan, issued by Nikkan Kogyo Shimbun, Ltd., 1977), JP-B 02-14431, JP-A 11-335858, JP-A 2003-13240, JP-A 2003-129249, JP-A 2006-111912, JP-A 2006-111914, JP-A 2006-274400, JP-A 2007-197743, etc.

After the step of treatment with the activation liquid for a silver mirror reaction, a step of activation by silver ions may be carried out. At this activation step, for example, a silver nitrate-containing liquid is preferably used for ease of treatment. Preferably, an aqueous dilute solution of silver nitrate at a concentration of 0.01 mol/L or less is brought into contact with the undercoat layer treated with stannous chloride. In the case where the silver ion treatment is carried out, the undercoat layer surface is preferably washed with deionized water after the silver ion treatment. At the activation step, spray coating is preferably employed in terms of continuous supply of a fresh liquid for coating.

The formation of the silver film layer by a silver mirror reaction is achieved by applying two solutions, i.e. an ammoniacal silver nitrate solution containing silver nitrate and ammonia, and a reducing agent solution containing a reducing agent and a strong alkali component, so as to allow the two solutions to be in a mixed state on the undercoat layer surface activated as above. As a result of the mixing, an oxidation-reduction reaction occurs to produce metal silver precipitates, which form a silver coating as a silver film layer on the undercoat layer surface.

The reducing agent solution is preferably an aqueous solution of an organic compound including saccharides such as dextrin, aldehyde compounds such as glyoxal, hydrazine compounds such as hydrazine sulfate, hydrazine carbonate and hydrazine hydrates; sodium sulfite; sodium thiosulfate; or the like.

For production of good-quality silver, several additives can be added to the aqueous ammoniacal silver nitrate solution. Examples of such additives include, but are not particularly limited to, amino alcohol compounds such as monoethanolamine, tris(hydroxymethyl)aminomethane, 2-amino-2-hydroxymethyl-1,3-propanediol, 1-amino-2-propanol, 2-amino-1-propanol, diethanolamine, diisopropanolamine, triethanolamine and triisopropanolamine; and amino acids or their salts such as glycine, alanine and glycine sodium salt.

Examples of the method for applying two solutions, i.e. the ammoniacal silver nitrate solution and the reducing agent solution, so as to allow the two solutions to be in a mixed state on the undercoat layer surface include spraying a previously prepared mixture of the two aqueous solutions on the undercoat layer surface with a spray gun or the like; spraying the two aqueous solutions with a concentric spray gun which has a structure allowing two aqueous solutions to be mixed in the head of the spray gun and immediately thereafter discharged from the spray gun; spraying the two aqueous solutions with a double head spray gun with two spray nozzles separately discharging the solutions; and spraying the two aqueous solutions simultaneously with two spray guns. Any of these methods can be selected depending on the circumstances.

Subsequently, the surface of the silver film layer is preferably washed with deionized water or purified distilled water for removal of the solutions and the like remaining on the surface after the silver mirror reaction. In order to stabilize the metal silver precipitates, the silver film layer can be treated with a solution containing an organic compound which is reactive to silver or has an affinity for silver before the formation of a topcoat layer on the silver film layer. For example, the silver film layer is dipped in the solution or the solution is applied on the silver film layer.

As the organic compound which is reactive to silver or has an affinity for silver, a nitrogen-containing heterocyclic compound having a thiol group or a thione group is used effectively, and the above-described heterocyclic compound having a thiol group and a hydrophobic group, and a Log P of 3.5 or more can also be used effectively. Examples of the heterocyclic ring of the nitrogen-containing heterocyclic compound include imidazole, imidazoline, triazole, thiazoline, oxazole, oxazoline, pyrazoline, triazole, thiadiazole, oxadiazole, tetrazole, pyridine, pyrimidine, pyridazine, pyrazine and triazine. Particularly preferred are imidazole, triazole and tetrazole. Specific examples of the nitrogen-containing heterocyclic compound include 2-mercapto-4-phenylimidazole, 2-mercapto-1-benzylimidazole, 2-mercapto-benzimidazole, 1-ethyl-2-mercapto-benzimidazole, 2-mercapto-1-butyl-benzimidazole, 1,3-diethyl-benzimidazoline-2-thione, 1,3-dibenzyl-imidazolidine-2-thione, 2,2′-dimercapto-1,1′-decamethylene-diimidazoline, 2-mercapto-4-phenylthiazole, 2-mercapto-benzothiazole, 2-mercapto-naphthothiazole, 3-ethyl-benzothiazoline-2-thione, 3-dodecyl-benzothiazoline-2-thione, 2-mercapto-4,5-diphenyloxazole, 2-mercaptobenzoxazole, 3-pentyl-benzoxazoline-2-thione, 1-phenyl-3-methylpyrazoline-5-thione, 3-mercapto-4-allyl-5-pentadecyl-1,2,4-triazole, 3-mercapto-5-nonyl-1,2,4-triazole, 3-mercapto-4-acetamide-5-heptyl-1,2,4-triazole, 3-mercapto-4-amino-5-heptadecyl-1,2,4-triazole, 2-mercapto-5-phenyl-1,3,4-thiadiazole, 2-mercapto-5-n-heptyl-oxathiazole, 2-mercapto-5-n-heptyl-oxadiazole, 2-mercapto-5-phenyl-1,3,4-oxadiazole, 2-heptadecyl-5-phenyl-1,3,4-oxadiazole, 5-mercapto-1-phenyl-tetrazole, 2-mercapto-5-nitropyridine, 1-methyl-quinoline-2(1H)-thione, 3-mercapto-4-methyl-6-phenyl-pyridazine, 2-mercapto-5,6-diphenyl-pyrazine, 2-mercapto-4,6-diphenyl-1,3,5-triazine, 2-amino-4-mercapto-6-benzyl-1,3,5-triazine and 1,5-dimercapto-3,7-diphenyl-s-triazolino[1,2-a]-s-triazoline.

### EXAMPLES

Hereinafter, the present invention will be illustrated in detail by examples, but the contents of the present invention are not limited thereto. Various modifications and alterations can be made without departing from the technical scope of the present invention. The percentage (%) and the mixing ratio are on a mass basis.

### Comparative Example 1

The surface of a polycarbonate plate was degreased, washed with water and dried, and the surface-treated plate was used as a substrate. An acrylic polyol-based urethane resin (manufactured by Ohashi Chemical Industries Ltd.; trade name: “Mirror Shine Undercoat Clear D1”), an isocyanate curing agent (manufactured by Ohashi Chemical Industries Ltd.; trade name: “Under Clear Curing Agent-N”), and an organic solvent (a mixture of methyl ethyl ketone and ethylene glycol monobutyl ether at the ratio of 1:1) were mixed at the ratio of 10:2:10 to prepare an undercoat paint. The substrate surface was spray-coated with the undercoat paint using a spray gun and then the coating surface was dried by heating at 80° C. for 2 hours, resulting in the formation of a 20-μm-thick undercoat layer on the substrate.

By addition of 0.15 mol of hydrochloric acid and 0.06 mol of stannous chloride to water, 1000 g of an activation liquid for a silver mirror reaction was prepared. The activation liquid for a silver mirror reaction was sprayed on the undercoat layer surface with a spray gun to activate the undercoat layer surface, and then the undercoat layer surface was washed with deionized water.

A liquid for electroless plating using a silver mirror reaction was prepared as follows. First, 20 g of silver nitrate was dissolved in 1000 g of deionized water to give a silver nitrate solution, and 100 g of a 28% aqueous ammonia solution and 5 g of monoethanolamine were dissolved in 1000 g of deionized water to give an ammonia solution. Just before use for silver film formation, the silver nitrate solution and the ammonia solution were mixed at the ratio of 1:1 to give an ammoniacal silver nitrate solution. Aside from this, 10 g of hydrazine sulfate, 5 g of monoethanolamine and 10 g of sodium hydroxide were dissolved in 1000 g of deionized water to give a reducing agent solution.

The thus-prepared ammoniacal silver nitrate solution and reducing agent solution were sprayed simultaneously using a double head spray gun to form a silver film layer on the activated undercoat layer. The surface of the silver film layer was washed with deionized water and then dried in a dryer at 70° C. for 30 minutes.

Next, a topcoat layer was formed on the silver film layer. A topcoat paint was prepared by mixing an acrylic silicone-based topcoat paint (manufactured by Ohashi Chemical Industries Ltd.; trade name: “O-MACK No. 100(E) Clear FV”), a silicone curing agent (manufactured by Ohashi Chemical Industries Ltd.; trade name: “Curing Agent W”), and an organic solvent (a mixture of methyl ethyl ketone and ethylene glycol monobutyl ether at the ratio of 1:1) at the ratio of 6:1:6, and adding 1-methylthiourea in an amount of 2.0% relative to the resin solid content of the topcoat layer. Here, the 1-methylthiourea added was in the form of a 2% solution in methyl isobutyl ketone. The silver film layer was spray-coated with the topcoat paint using a spray gun and then the coating surface was dried by heating at 80° C. for 60 minutes, resulting in the formation of a 15-μm-thick topcoat layer. In this manner, a silver-plated coated body having a silver film layer and a topcoat layer on the polycarbonate plate was obtained.

### Comparative Example 2

A silver-plated coated body was prepared in the same manner as in Comparative Example 1 except that 1,3-diethylthiourea was used instead of 1-methylthiourea in the topcoat layer.

### Comparative Example 3

A silver-plated coated body was prepared in the same manner as in Comparative Example 1 except that 1-naphthylthiourea was used instead of 1-methylthiourea in the topcoat layer.

### Example 1

A silver-plated coated body was prepared in the same manner as in Comparative Example 1 except that pentaerythritol tetrakis thiopropionate was used as an additional component in the topcoat layer in an amount of 7% relative to the resin solid content of the topcoat layer.

### Example 2

A silver-plated coated body was prepared in the same manner as in Comparative Example 2 except that trimethylolpropane tris(thiopropionate) was used as an additional component in the topcoat layer in an amount of 7% relative to the resin solid content of the topcoat layer.

### Example 3

A silver-plated coated body was prepared in the same manner as in Comparative Example 3 except that butanediol bis(thioglycolate) was used as an additional component in the topcoat layer in an amount of 7% relative to the resin solid content of the topcoat layer.

### Comparative Example 4

A silver-plated coated body was prepared in the same manner as in Comparative Example 1 except that 1-methylthiourea in the topcoat layer was replaced with 3-aminopropyltriethoxysilane in an amount of 10% relative to the resin solid content of the topcoat layer.

### Comparative Example 5

A silver-plated coated body was prepared in the same manner as in Comparative Example 1 except that 1-methylthiourea in the topcoat layer was replaced with 3-mercaptopropyltrimethoxysilane in an amount of 10% relative to the resin solid content of the topcoat layer.

### Comparative Example 6

A silver-plated coated body was prepared in the same manner as in Comparative Example 1 except that 1-methylthiourea in the topcoat layer was replaced with 3-isocyanatepropyltriethoxysilane in an amount of 10% relative to the resin solid content of the topcoat layer.

### Example 4

A silver-plated coated body was prepared in the same manner as in Example 1 except that 3-aminopropyltriethoxysilane was used as an additional component in the topcoat layer in an amount of 5% relative to the resin solid content of the topcoat layer.

### Example 5

A silver-plated coated body was prepared in the same manner as in Example 2 except that 3-aminopropyltriethoxysilane was used as an additional component in the topcoat layer in an amount of 5% relative to the resin solid content of the topcoat layer.

### Example 6

A silver-plated coated body was prepared in the same manner as in Example 3 except that 3-aminopropyltriethoxysilane was used as an additional component in the topcoat layer in an amount of 5% relative to the resin solid content of the topcoat layer.

The evaluation tests shown below were performed on the silver-plated coated bodies obtained in Examples 1 to 6 and Comparative Examples 1 to 6. The results are shown in Table 1.

### Evaluation Test Methods

### Evaluation a (Interlayer Adhesion)

Using a cutter guide (manufactured by Taiyu Co., Ltd.; trade name: “Super Cutter Guide”) and a commercial cutter blade, crosscuts were made at intervals of 2 mm on the topcoat layer surface of the silver-plated coated body so that the crosscuts would reach the polycarbonate substrate. Over the crosscut area, a piece of cellophane tape was attached to the topcoat layer surface with a firm pressure, and thereafter the cellophane tape was peeled off. The evaluation was performed according to the following criteria. “Poor” and “Very poor” are regarded as impossible for practical use.

Good: Coating layer separation is not observed at all.

Fair: Coating layer pieces have come off to a limited extent in the center of the crosscut area.

Poor: Coating layer separation is observed in the entire crosscut area.

Very poor: Coating layer separation is observed in the entire silver-plated coated body regardless of the presence of crosscuts.

Evaluation B (Tarnish after Heat Test)

The silver-plated coated body was stored in a heating cabinet (manufactured by Advantech Co., Ltd.; trade name: “THN054PB”) at 80° C. in a non-humidified environment for 10 days, and then left to stand at ordinary temperature for 2 hours. The appearance of the coating surface was rated by visual observation according to the criteria shown below. “Poor” and “Very poor” are regarded as impossible for practical use.

Good: No tarnish is found in comparison with an unheated product.

Fair: Tarnish is found in comparison with an unheated product, but is unrecognizable in an independent observation.

Poor: Tarnish is clearly found in an independent observation.

Very poor: The silver has been entirely blackened and has lost luster.

Evaluation C (Interlayer Adhesion after Salt Spray Test 1)

A salt spray test was carried out using a salt spray tester (manufactured by Suga Test Instruments Co., Ltd.; trade name: “STP-90”). Specifically, a 5% aqueous sodium chloride solution was sprayed on the silver-plated coated body at 35° C. for 5 days. After water washing and drying, crosscuts were made in the same manner as in Evaluation A. Over the crosscut area, a piece of cellophane tape was attached to the topcoat layer surface with a firm pressure, and thereafter the cellophane tape was peeled off. The evaluation was performed according to the same criteria as those in Evaluation A. “Poor” and “Very poor” are regarded as impossible for practical use.

Evaluation D (Interlayer Adhesion after Salt Spray Test 2)

On the silver-plated coated body, crosscuts were made in the same manner as in Evaluation A. Then, a salt spray test was carried out in the same manner as in Evaluation C, followed by water washing and drying. Over the crosscut area, a piece of cellophane tape was attached to the topcoat layer surface with a firm pressure, and thereafter the cellophane tape was peeled off. The evaluation was performed according to the same criteria as those in Evaluation A. “Poor” and “Very poor” are regarded as impossible for practical use.

TABLE 1

| | Evaluation | Evaluation | Evaluation | Evaluation |
|---|---|---|---|---|
| | A | B | C | D |
| Comparative | Good | Very poor | Fair | Poor |
| Example 1 | | | | |
| Comparative | Good | Poor | Fair | Very poor |
| Example 2 | | | | |
| Comparative | Fair | Fair | Poor | Very poor |
| Example 3 | | | | |
| Example 1 | Good | Fair | Good | Fair |
| Example 2 | Good | Fair | Good | Fair |
| Example 3 | Good | Fair | Good | Fair |
| Comparative | Good | Good | Poor | Poor |
| Example 4 | | | | |
| Comparative | Good | Poor | Fair | Poor |
| Example 5 | | | | |
| Comparative | Good | Good | Poor | Poor |
| Example 6 | | | | |
| Example 4 | Good | Good | Good | Good |
| Example 5 | Good | Good | Good | Good |
| Example 6 | Good | Good | Good | Good |

In the silver-plated coated bodies which were rated as Fair, Poor or Very poor in Evaluation A, C and D, coating layer separation was observed between the topcoat layer and the silver film.

### Example 7

An acrylic polyol-based urethane resin (manufactured by Ohashi Chemical Industries Ltd.; trade name: “Mirror Shine Undercoat Clear D1”), an epoxy resin (manufactured by ADEKA CORPORATION; trade name: “ADEKA RESIN EP-4000”; epoxy equivalent: 320), an isocyanate curing agent (manufactured by Ohashi Chemical Industries Ltd.; trade name: “Under Clear Curing Agent-N”), and an organic solvent (a mixture of methyl ethyl ketone and ethylene glycol monobutyl ether at the ratio of 1:1) were mixed at the ratio of 4:6:2:10 to prepare an undercoat paint. The silver-plated coated body of Example 7 was prepared in the same manner as in Example 4 except that this undercoat paint was used instead of the undercoat paint used in the preparation of the silver-plated coated body of Example 4.

### Example 8

An acrylic polyol-based urethane resin (manufactured by Ohashi Chemical Industries Ltd.; trade name: “Mirror Shine Undercoat Clear D1”), an epoxy resin (manufactured by ADEKA CORPORATION; trade name: “ADEKA RESIN EP-4000”), an isocyanate curing agent (manufactured by Ohashi Chemical Industries Ltd.; trade name: “Under Clear Curing Agent-N”), and an organic solvent (a mixture of methyl ethyl ketone and ethylene glycol monobutyl ether at the ratio of 1:1) were mixed at the ratio of 5:5:2:10 to prepare an undercoat paint. The silver-plated coated body of Example 8 was prepared in the same manner as in Example 4 except that this undercoat paint was used instead of the undercoat paint used in the preparation of the silver-plated coated body of Example 4.

### Example 9

An acrylic polyol-based urethane resin (manufactured by Ohashi Chemical Industries Ltd.; trade name: “Mirror Shine Undercoat Clear D1”), an epoxy resin (manufactured by ADEKA CORPORATION; trade name: “ADEKA RESIN EP-4000”), an isocyanate curing agent (manufactured by Ohashi Chemical Industries Ltd.; trade name: “Under Clear Curing Agent-N”), and an organic solvent (a mixture of methyl ethyl ketone and ethylene glycol monobutyl ether at the ratio of 1:1) were mixed at the ratio of 6:4:2:10 to prepare an undercoat paint. The silver-plated coated body of Example 9 was prepared in the same manner as in Example 4 except that this undercoat paint was used instead of the undercoat paint used in the preparation of the silver-plated coated body of Example 4.

### Example 10

An acrylic polyol-based urethane resin (manufactured by Ohashi Chemical Industries Ltd.; trade name: “Mirror Shine Undercoat Clear D1”), an epoxy resin (manufactured by ADEKA CORPORATION; trade name: “ADEKA RESIN EP-4000”), an isocyanate curing agent (manufactured by Ohashi Chemical Industries Ltd.; trade name: “Under Clear Curing Agent-N”), and an organic solvent (a mixture of methyl ethyl ketone and ethylene glycol monobutyl ether at the ratio of 1:1) were mixed at the ratio of 7:3:2:10 to prepare an undercoat paint. The silver-plated coated body of Example 10 was prepared in the same manner as in Example 4 except that this undercoat paint was used instead of the undercoat paint used in the preparation of the silver-plated coated body of Example 4.

### Example 11

An acrylic polyol-based urethane resin (manufactured by Ohashi Chemical Industries Ltd.; trade name: “Mirror Shine Undercoat Clear D1”), an epoxy resin (manufactured by ADEKA CORPORATION; trade name: “ADEKA RESIN EP-4000”), an isocyanate curing agent (manufactured by Ohashi Chemical Industries Ltd.; trade name: “Under Clear Curing Agent-N”), and an organic solvent (a mixture of methyl ethyl ketone and ethylene glycol monobutyl ether at the ratio of 1:1) were mixed at the ratio of 8:2:2:10 to prepare an undercoat paint. The silver-plated coated body of Example 11 was prepared in the same manner as in Example 4 except that this undercoat paint was used instead of the undercoat paint used in the preparation of the silver-plated coated body of Example 4.

### Example 12

An epoxy resin (manufactured by ADEKA CORPORATION; trade name: “ADEKA RESIN EP-4000”), a curing agent (meta-phenylenediamine), and an organic solvent (a mixture of methyl ethyl ketone and ethylene glycol monobutyl ether at the ratio of 1:1) were mixed at the ratio of 10:2:10 to prepare an undercoat paint. The silver-plated coated body of Example 10 was prepared in the same manner as in Example 4 except that this undercoat paint was used instead of the undercoat paint used in the preparation of the silver-plated coated body of Example 4.

In addition to Evaluations A to D, the evaluation tests shown below were performed on the silver-plated coated bodies obtained in Examples 4 and 7 to 12 and Comparative Example 1. These results are shown in Table 2.

### Evaluation Test Methods

Evaluation E (Interlayer Adhesion after Long-Term Salt Spray Test 1)

A salt spray test was carried out using a salt spray tester (manufactured by Suga Test Instruments Co., Ltd.; trade name: “STP-90”). Specifically, a 5% aqueous sodium chloride solution was sprayed on the silver-plated coated body at 35° C. for 42 days (about 1000 hours). After water washing and drying, crosscuts were made in the same manner as in Evaluation A. Over the crosscut area, a piece of cellophane tape was attached to the topcoat layer surface with a firm pressure, and thereafter the cellophane tape was peeled off. The evaluation was performed according to the same criteria as those in Evaluation A. “Very poor” is regarded as impossible for practical use.

Evaluation F (Interlayer Adhesion after Long-Term Salt Spray Test 2)

On the silver-plated coated body, crosscuts were made in the same manner as in Evaluation A. Then, a salt spray test was carried out in the same manner as in Evaluation F, followed by water washing and drying. Over the crosscut area, a piece of cellophane tape was attached to the topcoat layer surface with a firm pressure, and thereafter the cellophane tape was peeled off. The evaluation was performed according to the same criteria as those in Evaluation A. “Very poor” is regarded as impossible for practical use.

TABLE 2

| | Evalu- | Evalu- | Evalu- | Evalu- | Evalu- | Evalu- |
|---|---|---|---|---|---|---|
| | ation | ation | ation | ation | ation | ation |
| | A | B | C | D | E | F |
| Comparative | Good | Very | Fair | Poor | Very | Very |
| Example 1 | | poor | | | poor | poor |
| Example 4 | Good | Good | Good | Good | Fair | Poor |
| Example 7 | Good | Good | Good | Good | Good | Fair |
| Example 8 | Good | Good | Good | Good | Good | Good |
| Example 9 | Good | Good | Good | Good | Good | Good |
| Example 10 | Good | Good | Good | Good | Good | Good |
| Example 11 | Good | Good | Good | Good | Good | Fair |
| Example 12 | Good | Good | Good | Good | Fair | Poor |

In the silver-plated coated body of Comparative Example 1, coating layer separation was observed between the topcoat layer and the silver film in Evaluations C and D, and the silver film had been corroded and the coating layers were easily separable in Evaluations E and F. In the silver-plated coated bodies of Examples 4 and 12, coating layer separation was not observed between the topcoat layer and the silver film, but was observed between the undercoat layer and the silver film in Evaluations E and F. In the silver-plated coated bodies of Examples 7 and 11, coating layer separation was not observed between the topcoat layer and the silver film, but was observed between the undercoat layer and the silver film in Evaluation F.

### Examples 13 to 20

The silver-plated coated bodies of Examples 13 to 20 were prepared in the same manner as in Example 1 except that an aluminum plate whose surface had been degreased, washed with water and dried was used as a substrate instead of the polycarbonate plate, and that M4, M6, M7, M9, M14, M17, M22 or M24 (see [Chem. 1] of Paragraph [0051] and [Chem. 2] of Paragraph) was used as an additional additive in the topcoat layer in an amount of 0.5% relative to the resin solid content of the topcoat layer.

### Example 21

The silver-plated coated body of Example 21 was prepared in the same manner as in Example 1 except that M4 was used as an additional additive in the topcoat layer in an amount of 1% relative to the resin solid content of the topcoat layer.

### Example 22

The silver-plated coated body of Example 22 was prepared in the same manner as in Example 1 except that M14 was used as an additional component in the undercoat layer in an amount of 0.5% relative to the resin solid content of the undercoat layer.

### Comparative Examples 7 and 8

The silver-plated coated bodies of Comparative Examples 7 and 8 were prepared in the same manner as in Comparative Example 1 except that R1 or R2 (see [Chem. 3] of Paragraph [0104]) was added to the paint composition for the topcoat layer in an amount of 0.5% relative to the resin solid content of the topcoat layer.

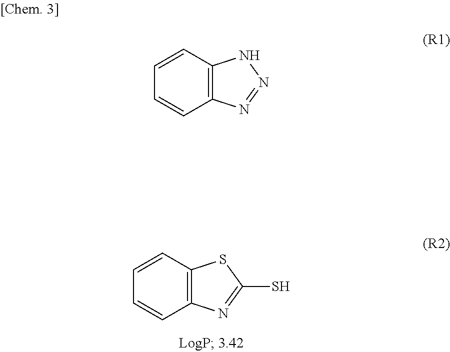 [SMILES: c1ccc2[nH]nnc2c1 ; Sc1nc2ccccc2s1]

The evaluation tests shown below were performed on the silver-plated coated bodies obtained in Examples 1 and 13 to 22 and Comparative Examples 1, 7 and 8. These results are shown in Table 3.

### Evaluation Test Methods

Evaluation G (Tarnish after Long-Term Heat Test)

The silver-plated coated body was stored in a heating cabinet (manufactured by Advantech Co., Ltd.; trade name: “THN054PB”) at 120° C. in a non-humidified environment for 4 months, and then left to stand at ordinary temperature for 2 hours. Then, using a spectrocolorimeter (manufactured by Konica Minolta Optics, Inc.; trade name: “CM-2500d”), the reflectance of the coating surface was measured in the SCI mode at a light wavelength of 400 nm, and the amount of change in reflectance with respect to the reflectance value measured on the coating surface of the corresponding unheated silver-plated coated body was determined. “Poor” and “Very poor” are regarded as impossible for practical use.

Excellent: The amount of change in reflectance is less than 8%.

Good: The amount of change in reflectance is from 8% to less than 10%.

Fair: The amount of change in reflectance is from 10% to less than 15%.

Poor: The amount of change in reflectance is from 15% to less than 40%.

Very poor: The amount of change in reflectance is 40% or more.

TABLE 3

| | | Amount of additional | | |
|---|---|---|---|---|
| | | additive relative to the | | |
| | | resin solid content (%) | | |
| | Additional | Topcoat | Undercoat | Evaluation |
| | additive | layer | layer | G |
| Comparative | — | — | — | Very poor |
| Example 1 | | | | |
| Example 1 | — | — | — | Fair |
| Example 13 | M4 | 0.5 | — | Excellent |
| Example 14 | M6 | 0.5 | — | Good |
| Example 15 | M7 | 0.5 | — | Good |
| Example 16 | M9 | 0.5 | — | Excellent |
| Example 17 | M14 | 0.5 | — | Excellent |
| Example 18 | M17 | 0.5 | — | Good |
| Example 19 | M22 | 0.5 | — | Excellent |
| Example 20 | M24 | 0.5 | — | Excellent |
| Example 21 | M4 | 1 | — | Excellent |
| Example 22 | M14 | — | 0.5 | Excellent |
| Comparative | R1 | 0.5 | — | Poor |
| Example 7 | | | | |
| Comparative | R2 | 0.5 | — | Poor |
| Example 8 | | | | |

The above results demonstrate that a silver-plated coated body that is excellent in interlayer adhesion and tarnish resistance can be obtained according to the present invention.

1. A silver-plated coated body having a silver film layer and a topcoat layer as essential layers on a substrate, the topcoat layer containing at least one kind selected from thiourea and thiourea derivatives, and at least one kind selected from thiol organic acids and thiol organic acid derivatives.

2. The silver-plated coated body according to claim 1, wherein the at least one kind selected from thiol organic acids and thiol organic acid derivatives is at least one kind selected from mercaptopropionic acid derivatives and thioglycolic acid derivatives.

3. The silver-plated coated body according to claim 1, wherein the topcoat layer further contains a silane coupling agent.

4. The silver-plated coated body according to claim 1, wherein an undercoat layer containing a urethane resin and/or an epoxy resin is present between the substrate and the silver film layer.

5. The silver-plated coated body according to claim 4, wherein the content ratio of the urethane resin to the epoxy resin (the ratio of the urethane resin content to the epoxy resin content) in the undercoat layer is 45:55 to 75:25 (mass ratio).

6. The silver-plated coated body according to claim 1, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

7. The silver-plated coated body according to claim 2, wherein the topcoat layer further contains a silane coupling agent.

8. The silver-plated coated body according to claim 2, wherein an undercoat layer containing a urethane resin and/or an epoxy resin is present between the substrate and the silver film layer.

9. The silver-plated coated body according to claim 3, wherein an undercoat layer containing a urethane resin and/or an epoxy resin is present between the substrate and the silver film layer.

10. The silver-plated coated body according to claim 7, wherein an undercoat layer containing a urethane resin and/or an epoxy resin is present between the substrate and the silver film layer.

11. The silver-plated coated body according to claim 8, wherein the content ratio of the urethane resin to the epoxy resin (the ratio of the urethane resin content to the epoxy resin content) in the undercoat layer is 45:55 to 75:25 (mass ratio).

12. The silver-plated coated body according to claim 9, wherein the content ratio of the urethane resin to the epoxy resin (the ratio of the urethane resin content to the epoxy resin content) in the undercoat layer is 45:55 to 75:25 (mass ratio).

13. The silver-plated coated body according to claim 10, wherein the content ratio of the urethane resin to the epoxy resin (the ratio of the urethane resin content to the epoxy resin content) in the undercoat layer is 45:55 to 75:25 (mass ratio).

14. The silver-plated coated body according to claim 2, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

15. The silver-plated coated body according to claim 3, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

16. The silver-plated coated body according to claim 7, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

17. The silver-plated coated body according to claim 5, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

18. The silver-plated coated body according to claim 11, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

19. The silver-plated coated body according to claim 12, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.

20. The silver-plated coated body according to claim 13, wherein an undercoat layer is present between the substrate and the silver film layer, and at least one selected from the undercoat layer and the topcoat layer contains a heterocyclic compound having a thiol group and a hydrophobic group, and an octanol/water partition coefficient (Log P) of 3.5 or more.
